(19) United States
(12) Patent Application Publication
(10) Pub. No.: US 2008/0064198 A1
(43) Pub. Date: Mar. 13, 2008

(54) Chalcogenide semiconductor memory device with insulating dielectric

(76) Inventors: Wolodymyr Czubatyj, Warren, MI (US); Tyler Lowrey, West Augusta, VA (US); Sergey Kostylev, Bloomfield Hills, MI (US)

Correspondence Address: TROP PRUNER & HU, PC, 1616 S. VOSS ROAD, SUITE 750, HOUSTON, TX, 77057-2631, US

(21) Appl. No.: 11/518,818

(22) Filed: Sep. 11, 2006

(51) Int. Cl. H01L 21/44

(52) U.S. Cl. 438/597

(57) ABSTRACT

A semiconductor chalcogenide containing memory device may be formed with a dielectric in close juxtaposition to a chalcogenide alloy. Because the dielectric includes material interface regions, the thermal conductivity of the dielectric is reduced. As one result, heat transfer may be reduced, reducing the programming current required to program the chalcogenide alloy.

### BACKGROUND

This invention relates generally to semiconductor memory devices using a chalcogenide alloy.

Phase change memory devices use phase change materials, i.e., materials that may be electrically switched between a generally amorphous and a generally crystalline state, for electronic memory application. One type of memory element utilizes a phase change material that may be, in one application, electrically switched between a structural state of generally amorphous and generally crystalline local order or between different detectable states of local order across the entire spectrum between completely amorphous and completely crystalline states. The state of the phase change materials is also non-volatile in that, when set in either a crystalline, semi-crystalline, amorphous, or semi-amorphous state representing a resistance value, that value is retained until changed by another programming event, as that value represents a phase or physical state of the material (e.g., crystalline or amorphous). The state is unaffected by removing electrical power.

### BRIEF DESCRIPTION OF THE DRAWINGS

FIG. 1 is an enlarged, cross-sectional view of one embodiment of the present invention;

FIG. 2 is an enlarged, cross-sectional view of still another embodiment of the present invention;

FIG. 3 is an enlarged, cross-sectional view of an apparatus for forming still another embodiment of the present invention; and

FIG. 4 is a system depiction in accordance with one embodiment of the present invention.

### DETAILED DESCRIPTION

It is desirable to reduce the programming current in semiconductor memory devices using a chalcogenide alloy, an example being a phase change memory or ovonic unified memory (OUM). Generally, these semiconductor memories use a chalcogenide material which may have different detectable states or different phases in some cases.

Commonly a programming current passes through the chalcogenide alloy. The lower the programming current, the less the power consumption of the overall memory, which may include a large number of cells, each of which may be programmed by the programming current and many may be programmed in parallel

The programming current heats the chalcogenide material. The lower the heat loss from the heated chalcogenide material, the less programming current that may be needed. One way to reduce the heat loss is to provide better insulation around the chalcogenide alloy.

In some cases, the programming current does not decrease linearly with area because of the heat lost to the insulator surrounding the chalcogenide alloy. In some embodiments of the present invention, it has been determined that using materials with different acoustic impedance to form a dielectric in close proximity to the heated chalcogenide alloy or the alloy heater may reduce heat loss.

Without being limited to theory, thermal conductivity may be reduced in a dielectric because of the thermal interface resistance between two different dielectric materials used to make the dielectric. Two materials with different acoustic impedance in contact with one another may reduce thermal conductivity because the phonons that transport thermal energy bounce off this impedance mismatch interface, increasing thermal resistance through the material. If the dielectric is a heterogeneous mixture of two dielectric materials with different acoustic impedances, the same effect may apply.

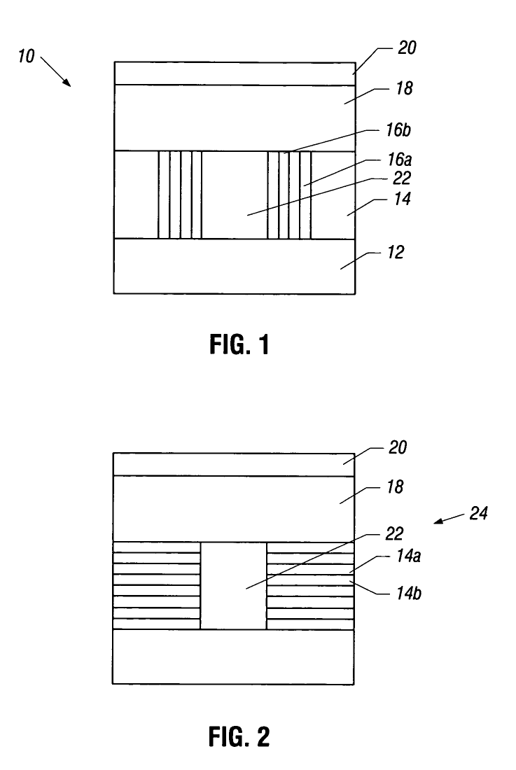

Thus, referring to FIG. 1, in accordance with one embodiment, a chalcogenide containing semiconductor memory device 10 may include a substrate with a lower electrode 12. Over the substrate and the lower electrode 12 may be an upper electrode 20. In some cases, the electrodes 12 and 20 may be transversely oriented with respect to one another.

A dielectric 14 over the electrode 12 may have an aperture or pore. The dielectric 14 aperture or pore may be filled with alternating layers 16a and 16b of a different dielectric material. For example, the dielectric layer 14 may be an oxide, the dielectric layer 16a may be any oxide, nitride, or sulfide and the dielectric layer 16b may be any oxide, nitride, or sulfide, to give a few examples. Thus, an acoustic impedance mismatch interface occurs between the distinct layers, decreasing the thermal conductivity. The vertical layers may be made, for example, by chemical vapor deposition, followed by cleaning of the electrode 12 as necessary.

A heater 22 may be provided centrally with the pore. Electric current passing through the heater 22 creates heat via the Joule effect. The current proceeds through the chalcogenide alloy 18. Thus, an electrically conducting path is made up of the electrodes 12 and 20, the heater 22, and the chalcogenide alloy 18. The chalcogenide alloy 18 also produces heat in the vicinity of the heater contact while being heated by the heater 22, may transition between two or more detectable states or phases in some embodiments.

In other embodiments, the chalcogenide alloy 18 may be formed completely or partially within the pore in the dielectric 14. Many other designs for the phase change memory may be used as well.

Referring to FIG. 2, in accordance with another embodiment, in a similar arrangement the layers 14a and 14b are horizontally disposed with respect to one another. Thus, the alternating layers of at least two different dielectric materials creates an acoustic impedance boundary, as described above with respect to the vertically oriented layers 16a and 16b. The layers 14a and 14b may be made, for example, of any of the materials described above with respect to the layers 16a and 16b.

In accordance with another embodiment of the present invention, dielectric layer 14 with low thermal conductivity may be provided by co-sputtering different materials. In some cases, the vertically or horizontally oriented distinct layers can be used as well. Thus, one co-sputtered material may be different from the other co-sputtered material and the two materials may be sputtered to form the dielectric 14. In one embodiment, alternating atomic layers of different materials may be used. In other embodiments, one or more layers may have a mixture of at least two different materials.

In still another embodiment, mixed layers of two different materials may be alternated with succeeding layers of different materials. In such case, phonon boundaries may be created within a layer and between layers.

In one embodiment, the co-sputtering may be from a composite target such as ZnS/SiO₂ targets. In another embodiment, microporous materials, such as Xerogels or porous silicon dioxide may be used for low dielectric constant dielectrics. In some embodiments, the two material dielectric has a thermal conductivity lower than the thermal conductivity of either of the constituent materials.

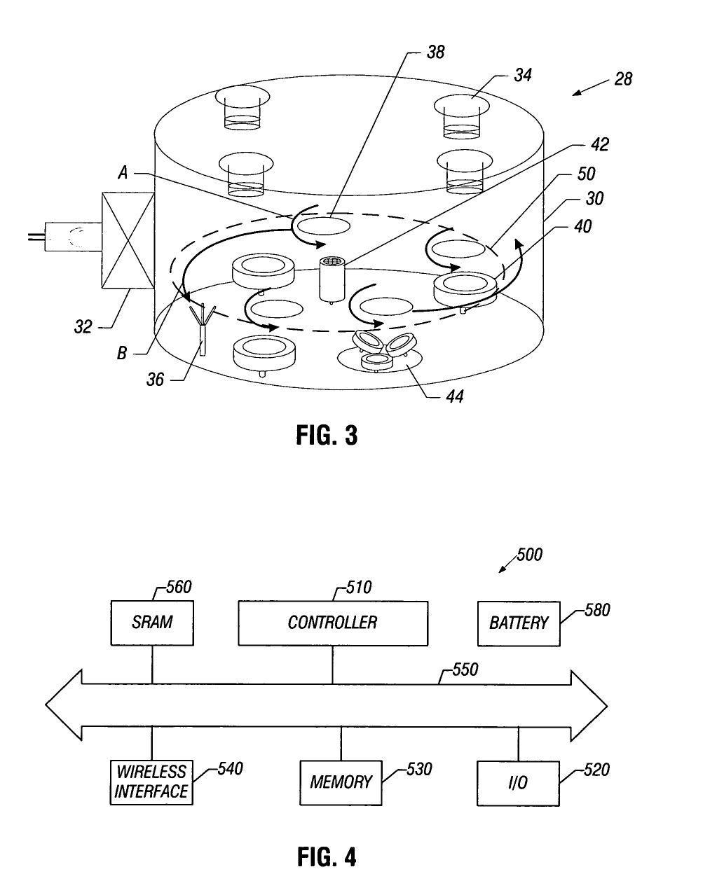

Referring to FIG. 3, a co-sputtering apparatus 28 may include a vacuum process chamber 30 into which semiconductor wafers may be loaded via a load lock 32. The load lock chamber is evacuated after the sample is loaded and before it is introduced into the process chamber. The process chamber 30 is always under vacuum for maximum cleanliness and lowest residual gas contamination. The loaded wafers may have a substrate with many integrated circuits formed thereon, each including the lower electrode 12.

A plurality of lamp heaters 34 may be provided on the uppermost wall of the chamber 30. The heaters 34 heat the upwardly exposed back sides of the wafers 38 mounted on the pallet 44. An ion source 42 may be used for cleaning the wafers before deposition.

The targets 40 are a single sputtering targets and the target 44 is an example of a cluster tool with three sputtering targets for co-sputtering. Thus, a wafer 38 may be positioned over the three targets of the cluster tool 44. Thus, three different materials may be co-sputtering onto the wafers 38.

The wafers 38 may be rotated by the apparatus in the direction of the arrows A, as one example. Wafers may be transferred onto the pallet from the load-locked chamber via the mechanical wafer transfer arm 36. In addition, the pallet 50 on which the wafers are mounted rotates around the center of the chamber 30 in the direction of the arrows B in one embodiment. The wafers 38 may be mounted on a pallet so that their back sides are exposed to the lamps 34 and their front sides are exposed, via openings in the pallet 50 to the sputter targets 40 or 44. Thus, the pallet 50 rotates the wafers as indicated and exposes them both to the lamps 34 and the material being sputtered by targets 40 or 44. Pallets of this type are well known to those skilled in the art.

While co-sputtering is described herein, alternating layer, atomic layer deposition, or chemical vapor deposition may also be used in other embodiments.

While the dielectric 14 is shown surrounding the heater 22, it may also partially surround the chalcogenide 18.

Programming of the chalcogenide alloy 18 to alter the state or phase of the material may be accomplished by applying voltage potentials to the lower electrode 12 and upper electrode 20, thereby generating a voltage potential across the select device and memory element. When the voltage potential is greater than the threshold voltages of select device and memory element, then an electrical current may flow through the chalcogenide alloy 18 in response to the applied voltage potentials, and may result in heating of the chalcogenide alloy 18.

This heating may alter the memory state or phase of the chalcogenide alloy 18. Altering the phase or state of the chalcogenide alloy 18 may alter the electrical characteristic of memory material, e.g., the resistance of the material may be altered by altering the phase of the memory material. Memory material may also be referred to as a programmable resistive material.

In the “reset” state, memory material may be in an amorphous or semi-amorphous state and in the “set” state, memory material may be in a crystalline or semi-crystalline state. The resistance of memory material in the amorphous or semi-amorphous state may be greater than the resistance of memory material in the crystalline or semi-crystalline state. It is to be appreciated that the association of reset and set with amorphous and crystalline states, respectively, is a convention and that at least an opposite convention may be adopted.

Using electrical current, memory material may be heated to a relatively higher temperature and subsequently quenched to amorphise the memory material and “reset” memory material (e.g., program memory material to a logic “0” value). Heating the volume of memory material to a relatively lower crystallization temperature may crystallize memory material and “set” memory material (e.g., program memory material to a logic “1” value). Various resistances of memory material may be achieved to store information by varying the amount of current flow and duration through the volume of memory material.

A select device may operate as a switch that is either “off” or “on” depending on the amount of voltage potential applied across the memory cell, and more particularly whether the current through the select device exceeds its threshold current or voltage, which then triggers the device into the on state. The off state may be a substantially electrically nonconductive state and the on state may be a substantially conductive state, with less resistance than the off state.

In the on state, the voltage across the select device, in one embodiment, is equal to its holding voltage V_{H} plus I*Ron, where Ron is the dynamic resistance from the extrapolated X-axis intercept, V_{H}. For example, a select device may have threshold voltages and, if a voltage potential less than the threshold voltage of a select device is applied across the select device, then the select device may remain “off” or in a relatively high resistive state so that little or no electrical current passes through the memory cell and most of the voltage drop from selected row to selected column is across the select device. Alternatively, if a voltage potential greater than the threshold voltage of a select device is applied across the select device, then the select device may “turn on,” i.e., operate in a relatively low resistive state so that electrical current passes through the memory cell. In other words, one or more series connected select devices may be in a substantially electrically nonconductive state if less than a predetermined voltage potential, e.g., the threshold voltage, is applied across select devices. Select devices may be in a substantially conductive state if greater than the predetermined voltage potential is applied across select devices. Select devices may also be referred to as an access device, an isolation device, or a switch.

One or more MOS or bipolar transistors, an ovonic threshold switch, or one or more diodes (either MOS or bipolar) may be used as the select device. If a diode is used, the bit may be selected by lowering the row line from a higher deselect level. As a further non-limiting example, if an n-channel MOS transistor is used as a select device with its source, for example, at ground, the row line may be raised to select the memory element connected between the drain of the MOS transistor and the column line. When a single MOS or single bipolar transistor is used as the select device, a control voltage level may be used on a “row line” to turn the select device on and off to access the memory element.

Turning to FIG. 4, a portion of a system 500 in accordance with an embodiment of the present invention is described. System 500 may be used in wireless devices such as, for example, a personal digital assistant (PDA), a laptop or portable computer with wireless capability, a web tablet, a wireless telephone, a pager, an instant messaging device, a digital music player, a digital camera, or other devices that may be adapted to transmit and/or receive information wirelessly. System 500 may be used in any of the following systems: a wireless local area network (WLAN) system, a wireless personal area network (WPAN) system, a cellular network, although the scope of the present invention is not limited in this respect.

System 500 may include a controller 510, an input/output (I/O) device 520 (e.g. a keypad, display), static random access memory (SRAM) 560, a memory 530, and a wireless interface 540 coupled to each other via a bus 550. A battery 580 may be used in some embodiments. It should be noted that the scope of the present invention is not limited to embodiments having any or all of these components.

Controller 510 may comprise, for example, one or more microprocessors, digital signal processors, microcontrollers, or the like. Memory 530 may be used to store messages transmitted to or by system 500. Memory 530 may also optionally be used to store instructions that are executed by controller 510 during the operation of system 500, and may be used to store user data. Memory 530 may be provided by one or more different types of memory. For example, memory 530 may comprise any type of random access memory, a volatile memory, a non-volatile memory such as a flash memory and/or a memory such as memory discussed herein.

I/O device 520 may be used by a user to generate a message. System 500 may use wireless interface 540 to transmit and receive messages to and from a wireless communication network with a radio frequency (RF) signal. Examples of wireless interface 540 may include an antenna or a wireless transceiver, although the scope of the present invention is not limited in this respect.

References throughout this specification to “one embodiment” or “an embodiment” mean that a particular feature, structure, or characteristic described in connection with the embodiment is included in at least one implementation encompassed within the present invention. Thus, appearances of the phrase “one embodiment” or “in an embodiment” are not necessarily referring to the same embodiment. Furthermore, the particular features, structures, or characteristics may be instituted in other suitable forms other than the particular embodiment illustrated and all such forms may be encompassed within the claims of the present application.

While the present invention has been described with respect to a limited number of embodiments, those skilled in the art will appreciate numerous modifications and variations therefrom. It is intended that the appended claims cover all such modifications and variations as fall within the true spirit and scope of this present invention.

What is claimed is:

1. A method comprising:
forming a dielectric on a substrate, said dielectric formed of at least two different materials that meet along an interface;
forming a chalcogenide alloy in juxtaposition to said dielectric; and
providing electrodes on either side of said chalcogenide alloy.

2. The method of claim 1 including forming distinct dielectric layers of at least two different materials.

3. The method of claim 2 including forming horizontally disposed layers.

4. The method of claim 2 including forming vertically disposed layers.

5. The method of claim 1 including forming said dielectric of two separately deposited materials.

6. The method of claim 5 including co-sputtering at least two materials to form said dielectric.

7. The method of claim 1 including forming a pore in said dielectric and a heater in said pore.

8. The method of claim 7 including forming said alloy over said heater.

9. The method of claim 7 including forming said dielectric around said heater.

10. The method of claim 1 including forming a dielectric layer formed of two materials, said dielectric layer having a thermal conductivity lower than the thermal conductivity of either of said materials.

11. A chalcogenide memory comprising:
a substrate;
a lower electrode;
a heater coupled to said lower electrode;
a chalcogenide layer coupled to said lower electrode;
an upper electrode coupled to said chalcogenide layer; and
a dielectric proximate to said heater, said dielectric including at least two distinct materials, said materials meeting at a material interface.

12. The memory of claim 11 wherein said dielectric includes horizontally disposed layers.

13. The memory of claim 11 wherein said dielectric includes vertically disposed layers.

14. The memory of claim 11 wherein said dielectric includes two co-sputtered materials.

15. The memory of claim 11 including a pore in said dielectric, and said heater in said pore.

16. The memory of claim 15 including said chalcogenide on said heater.

17. The memory of claim 16 wherein said dielectric surrounds said heater.

18. The memory of claim 11 wherein said dielectric has a thermal conductivity lower than the thermal conductivity of either of its constituent materials.

19. The memory of claim 11 wherein said memory is a phase change memory.

20. A system comprising:
a processor;
a memory coupled to said processor, said memory including a pair of electrodes surrounding a heater and a chalcogenide layer; and
a dielectric proximate to said chalcogenide layer, said dielectric including at least two distinct materials, said materials having a material interface between said materials.

21. The system of claim 20 wherein said dielectric includes horizontally disposed layers of two different materials.

22. The system of claim 20 wherein said dielectric includes vertically disposed layers of two different materials.

23. The system of claim 20 wherein said dielectric includes at least two distinct materials, said materials forming a single layer and each of said materials defining discrete regions within said layer.
